(19) United States
(12) Patent Application Publication
(10) Pub. No.: US 2013/0277741 A1
(43) Pub. Date: Oct. 24, 2013

(54) LDMOS DEVICE WITH FIELD EFFECT STRUCTURE TO CONTROL BREAKDOWN VOLTAGE, AND METHODS OF MAKING SUCH A DEVICE

(71) Applicants: Zhang Guowei, Singapore (SG); Purakh Raj Verma, Singapore (SG)

(72) Inventors: Zhang Guowei, Singapore (SG); Purakh Raj Verma, Singapore (SG)

(73) Assignee: GLOBALFOUNDRIES SINGAPORE PTE LTD, Singapore (SG)

(21) Appl. No.: 13/453,222

(22) Filed: Apr. 23, 2012

(51) Int. Cl. H01L 29/78

(52) U.S. Cl. 257/343; 257/E29.256

(57) ABSTRACT

In one embodiment of an LDMOS device disclosed herein, the device includes a source region, a drain region and a gate electrode that are formed in and above a semiconducting substrate, wherein the gate electrode is generally laterally positioned between the source region and the drain region, a metal-1 field plate positioned above the gate electrode, and a silicide block layer that is positioned in an area between the gate electrode and the drain region. The device further includes at least one source contact that is conductively coupled to the metal-1 field plate and a conductive structure that is conductively coupled to the metal-1 field plate, wherein at least a first portion of the conductive structure extends downward toward the substrate in the area between the gate electrode and the drain region.

### BACKGROUND OF THE INVENTION

1. Field of the Invention

Generally, the present disclosure relates to the manufacture of sophisticated semiconductor devices, and, more specifically, to various embodiments of a novel LDMOS (Lateral Double Diffused Metal Oxide Semiconductor) field effect transistor device with a novel field effect structure and various methods of making such an LDMOS device.

2. Description of the Related Art

LDMOS transistors are used in many applications, such as power management for cell phones, ADSL drivers, LED displays, LCD display drivers, high power amplifiers for wireless base stations, etc. LDMOS devices are typically formed in an epitaxial layer deposited or grown on a semiconductor substrate. An LDMOS transistor has a source region separated from an extended drain region by a channel. The dopant distribution in the channel region is formed by lateral diffusion of dopants from the source side of the channel region, forming a laterally graded channel region. The source region and extended drain region are of the same conductivity type (e.g., N-type), while the epitaxial layer and the channel region are of the opposite conductivity type (e.g., P-type). A gate actuates the LDMOS transistor. LDMOS transistors are used extensively in RF applications because of their advantageous linearity, power gain and breakdown voltage characteristics.

FIGS. 1A-1B schematically depict an illustrative embodiment of a prior art LDMOS device 11, wherein FIG. 1A is a cross-sectional view of such a device 11 and FIG. 1B is a schematically depicted plan view of various portions of such a device 11. As shown in FIG. 1A, the illustrative LDMOS device 11 is formed above a semiconducting substrate 10. Various isolation regions 12 are formed in the substrate 10 using traditional techniques. The device 11 is generally comprised of a P-well 14, an N-doped drift region 16, an N+-doped source region 18, an N+-doped drain region 20 and a P+-doped well tap 21 formed in the substrate 10. The LDMOS device 11 further comprises a gate electrode 30, a gate insulation layer 32, sidewall spacers 34, a plurality of metal silicide regions 22, a pad oxide layer 26, a so-called silicide-block layer 28 (in some cases, the combination of the layers 26 and 28 may be referred to as the silicide block layer), a layer of insulating material 24, such as a silicon nitride material, and an ILD layer 46, such as silicon dioxide. In operation, an illustrative channel region 17 may be established under the gate electrode 30. The device 11 further includes a metal-1 field plate 40, a plurality of source region contacts 42, a plurality of P-well region contacts 43, a plurality of drain region contacts 52 and a metal connection for the drain contact 50. The metal-1 field plate 40 and the contacts 42, 43 are adapted to be coupled to a relatively low voltage (“V_{LOW}”), while the drain region contact 52 and the drain contact 50 are adapted to be coupled to a relatively higher voltage (“V_{HIGH}”). In one illustrative embodiment, the V_{LOW} voltage may be about 0 volts while the V_{HIGH} voltage may be about 10-50 volts. Of course, the absolute values for the applied voltages V_{LOW} and V_{HIGH} may vary depending upon the particular application.

FIG. 1B is a schematically depicted plan view of portions of the LDMOS device 11 depicted in FIG. 1A. As shown therein, the P+-doped well tap 21, the N+-doped source region 18, the N-doped drift region 16 and the N+-doped drain region 20 are formed within an active area 25 defined in the substrate 10 by the isolation structures 12 (which are not depicted in FIG. 1B). The gate electrode 30 is also depicted in FIG. 1B for reference purposes. The configuration of the illustrative metal-1 field plate 40 is depicted by dashed lines in FIG. 1B so as to show the various structures positioned underneath the metal-1 field plate 40. As shown in FIGS. 1A and 1B, the metal-1 field plate 40 is conductively coupled to the contacts 42, 43. Typically, the drain side edge 40D of the metal-1 field plate 40 extends past the drain side edge 30D of the gate electrode 30 but it does not extend all of the way to the inner edge 20E1 of the drain region 20.

A device that can operate at a high voltage close to a theoretical breakdown voltage of a semiconductor is preferred as an ideal power semiconductor device. Accordingly, in a case where an external system using a high voltage is controlled by an integrated circuit (IC), the IC needs a high voltage control device built therein and configured to have a high breakdown voltage. LDMOS devices have a structure suitable for a high voltage because the channel region 17 and the drain region 20 thereof are separated with a drift region 16 disposed therebetween. Ideally, at the point of maximum (breakdown) voltage, the extended drain region of an LDMOS transistor is fully depleted of charge carriers. High electric fields in the LDMOS transistor are reduced when the extended drain region is fully depleted. Electric fields in an LDMOS transistor are more evenly dispersed over the length of the extended drain region when the extended drain region is fully depleted. Accordingly, the breakdown voltage of an LDMOS transistor is greatest when the extended drain region is fully depleted. The extended drain region may be depleted by lightly doping the elongated drift portion 16 of the extended drain. However, a lightly-doped drift region 16 increases the on-state resistance (RDSₒₙ) of the LDMOS device 11, which degrades RF performance.

Ideally, it is desirable to have the breakdown voltage of an LDMOS device be as high as possible while keeping the on-state resistance as low as possible. However, processing techniques employed to achieve these two objectives typically contradict one another, thereby presenting a key trade-off situation as it relates to the ultimate performance of an LDMOS device. For example, the breakdown voltage of the LDMOS device 11 may be increased by reducing the doping levels in the drift region 16, but this reduction in the doping levels of the drift region 16 increases the on-state resistance of the device 11. Thus, the key for the design of LDMOS devices is to increase the breakdown voltage without increasing the on-state resistance, or reducing the on-state resistance without reducing the breakdown voltage of the device. Historically, LDMOS device designers have used a structure similar to the metal-1 field plate structure 40 described above with respect to FIGS. 1A-1B in an attempt to increase the breakdown voltage of the device 11 without increasing the on-state resistance.

Typically, breakdown hot spots happen near the drain side edge 30D of the gate electrode 30 where the electrical field is high. The prior art metal-1 field plate 40 was employed in an attempt to force the hot spots to move away from drain side edge 30D of the gate electrode 30 by moving the zero potential point away from the gate electrode 30. However, the typical metal-1 field plate 40 in prior art devices is located at the so-called “metal-1” level, and it is typically positioned in the ILD layer 46 that may be relatively thick, e.g., 600 nm or greater. As a result, the improvement associated with increasing breakdown voltage by using such illustrative metal-1 field plates 40 with such prior art LDMOS devices is typically not that significant.

Generally, the present disclosure is directed to various embodiments of a novel LDMOS device with a novel field effect structure and various methods of making such an LDMOS device.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various embodiments of a novel LDMOS device with a novel field effect structure and various methods of making such an LDMOS device. In one embodiment of an LDMOS device disclosed herein, the device includes a source region, a drain region and a gate electrode that are formed in and above a semiconducting substrate, wherein the gate electrode is generally laterally positioned between the source region and the drain region, a metal-1 field plate positioned above the gate electrode, and a silicide block layer that is positioned in an area between the gate electrode and the drain region. The device further includes at least one source contact that is conductively coupled to the metal-1 field plate and a conductive structure that is conductively coupled to the metal-1 field plate, wherein at least a first portion of the conductive structure extends downward toward the substrate in the area between the gate electrode and the drain region.

In further embodiments, the conductive structures may take the form of conductive contacts, conductive rings, conductive line-type features or a conductive plate. Regardless of the form of the conductive structures, they are conductively coupled to the source, body or gate through the metal-1 layer. In even further, more detailed embodiments, at least some of the conductive features land on the silicide block layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B depict one illustrative embodiment of a prior art LDMOS device;

FIGS. 2A-2I depict various illustrative embodiments of various novel LDMOS devices disclosed herein, and various methods of making such devices; and

FIGS. 3A-3C depict one illustrative process flow for manufacturing one of the novel LDMOS devices disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

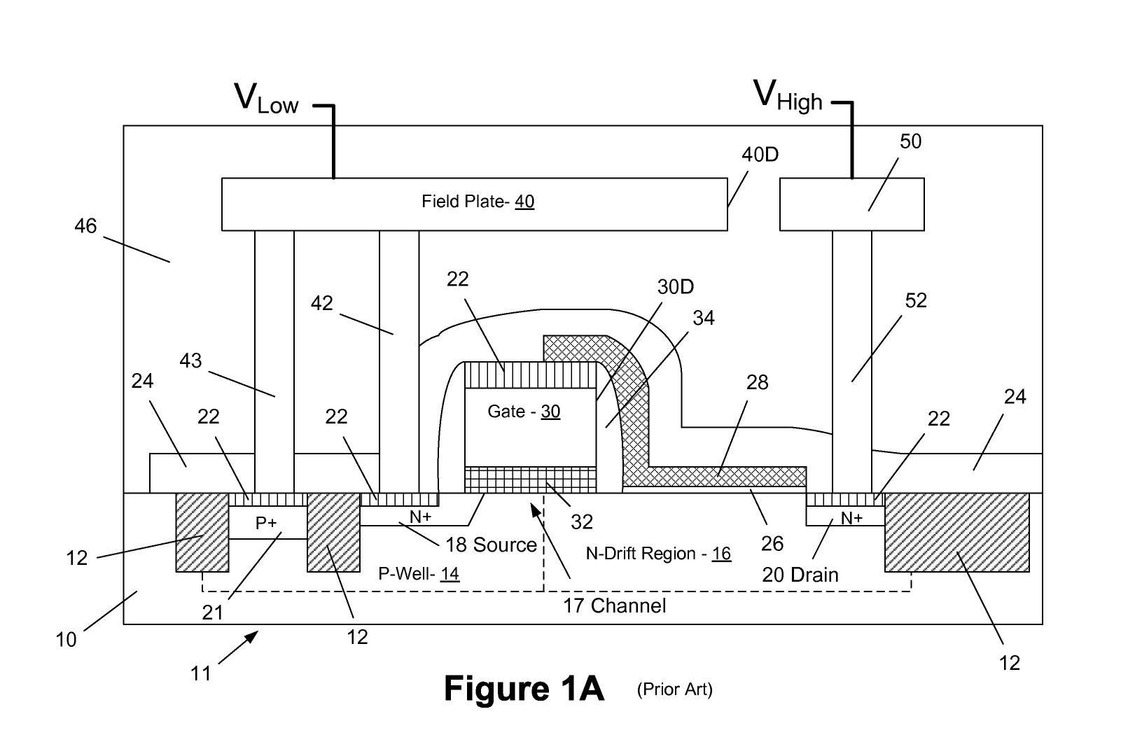

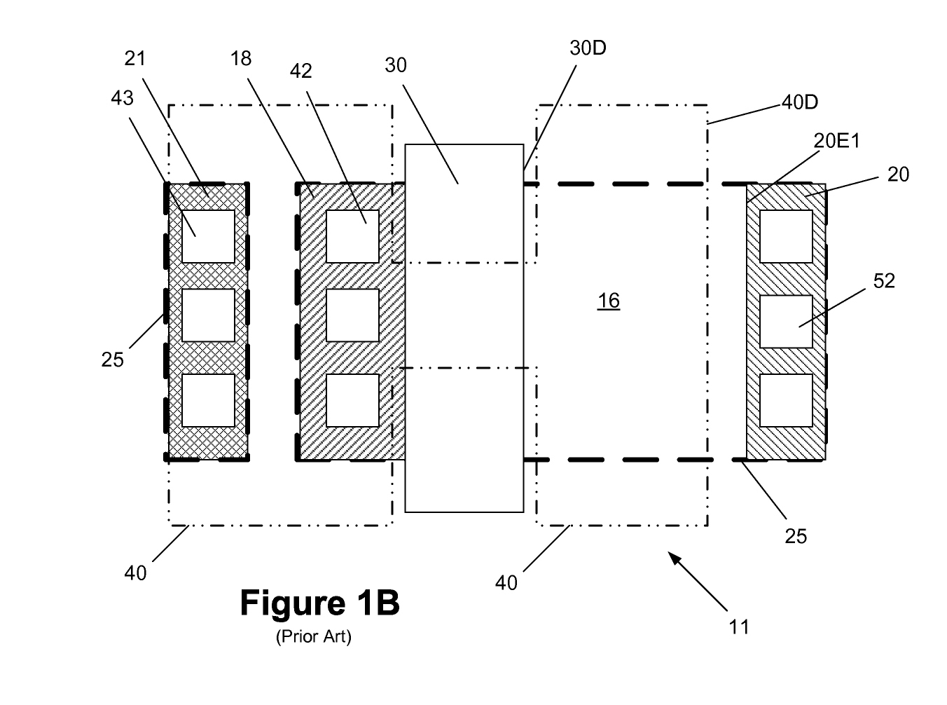

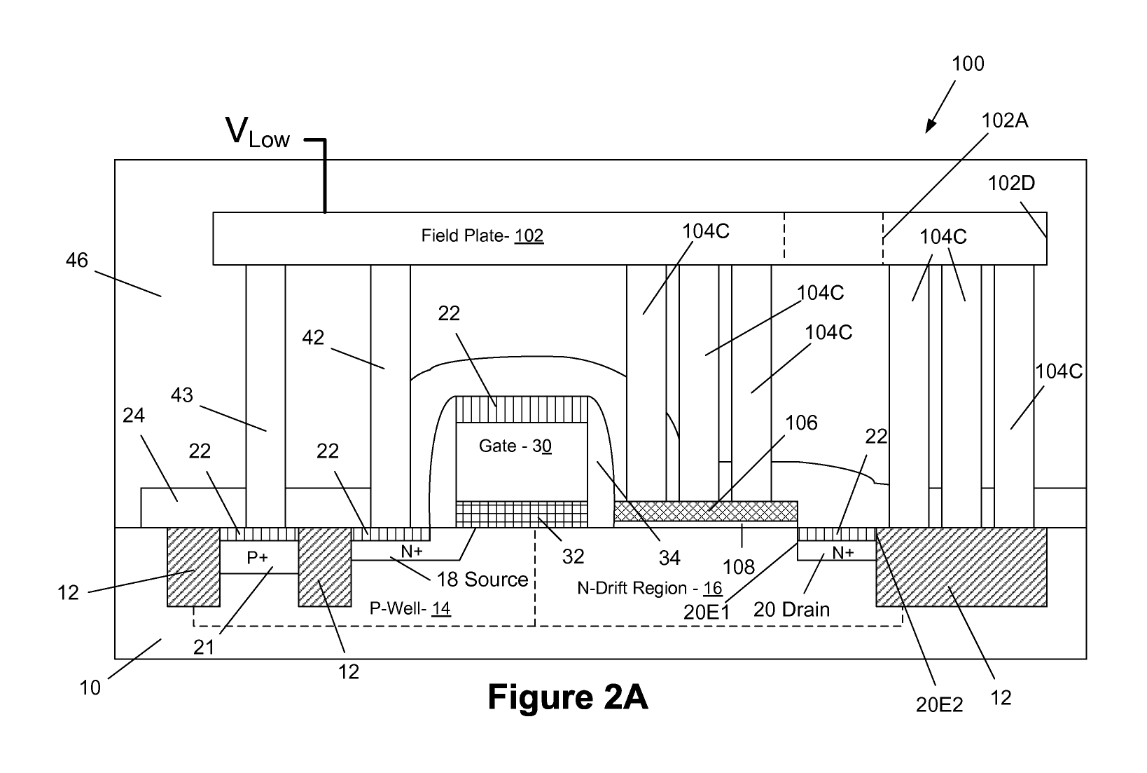

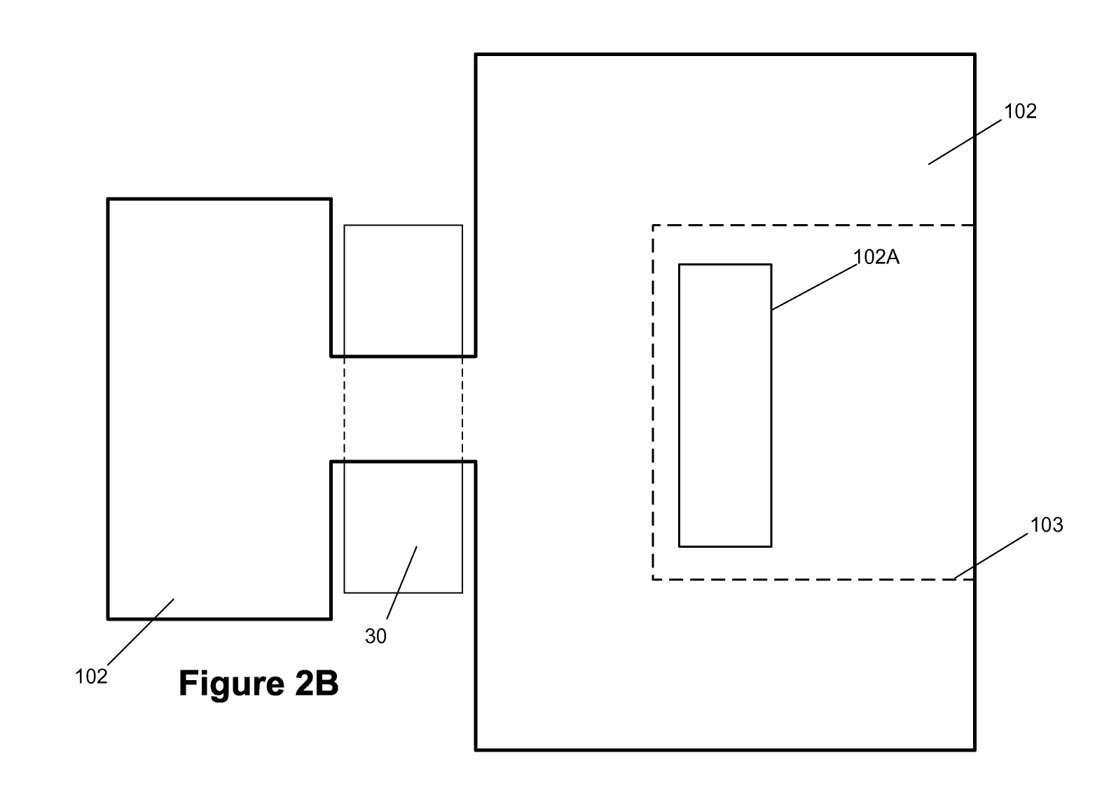

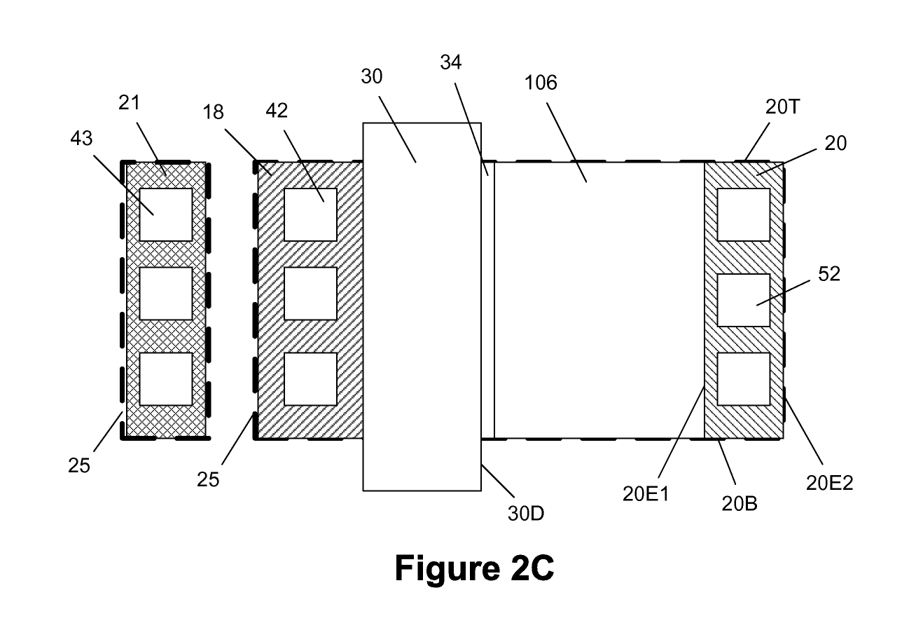

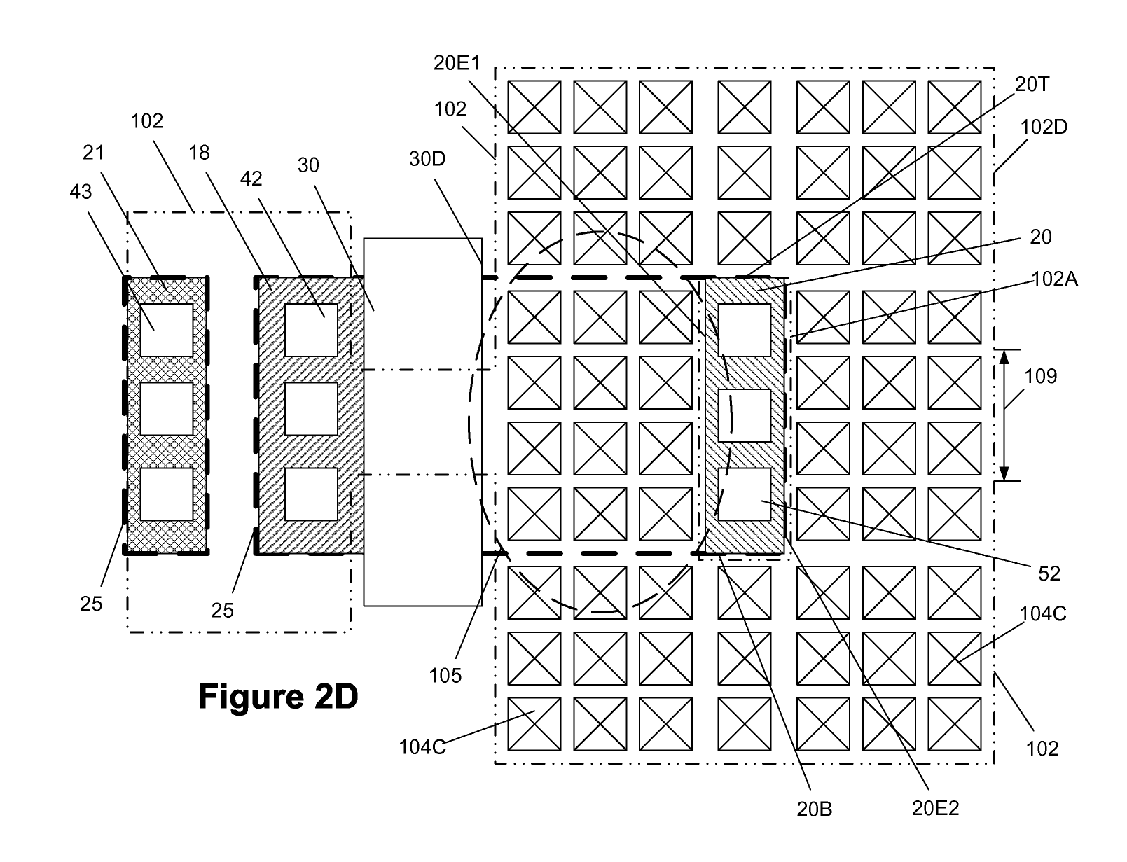

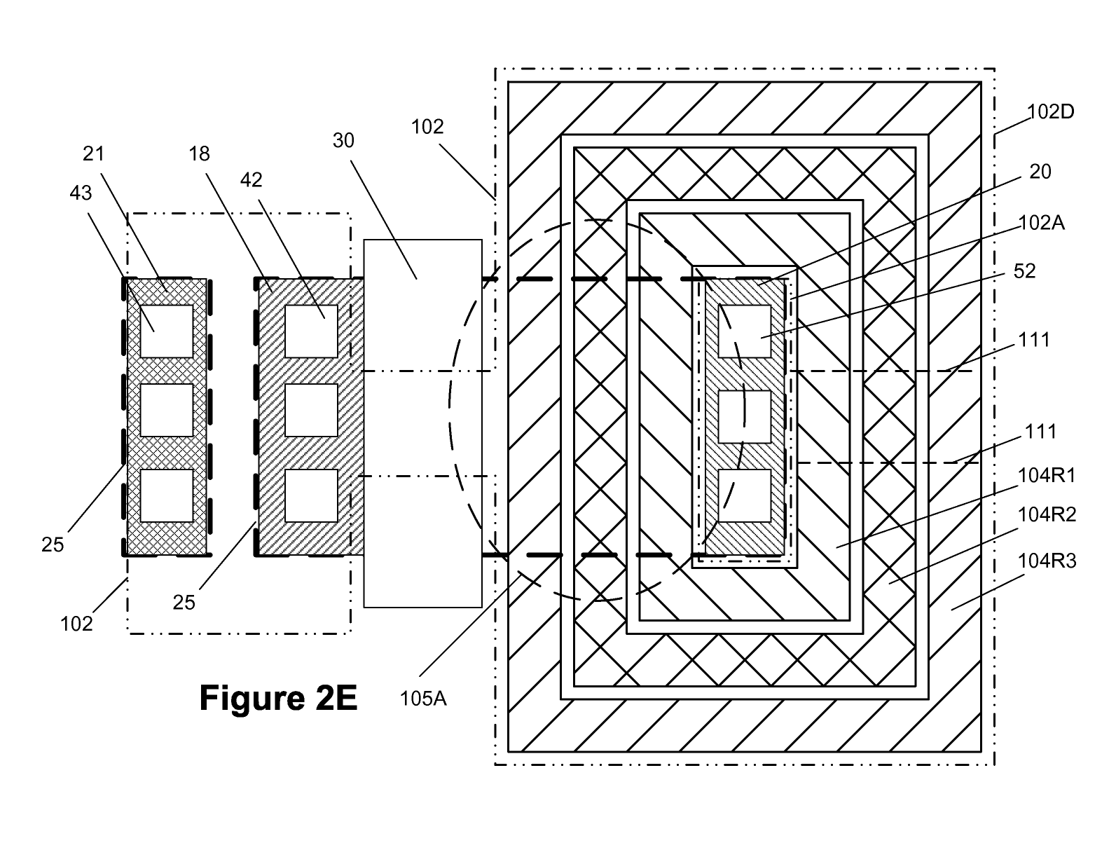

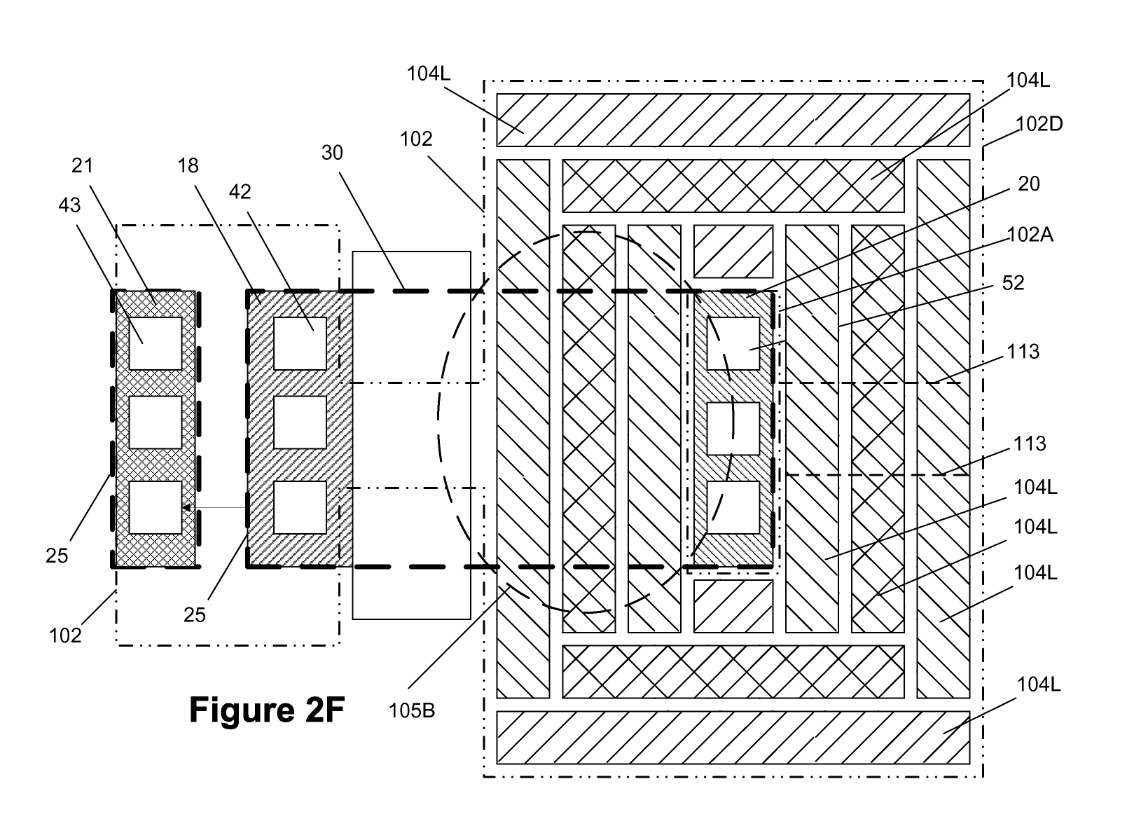

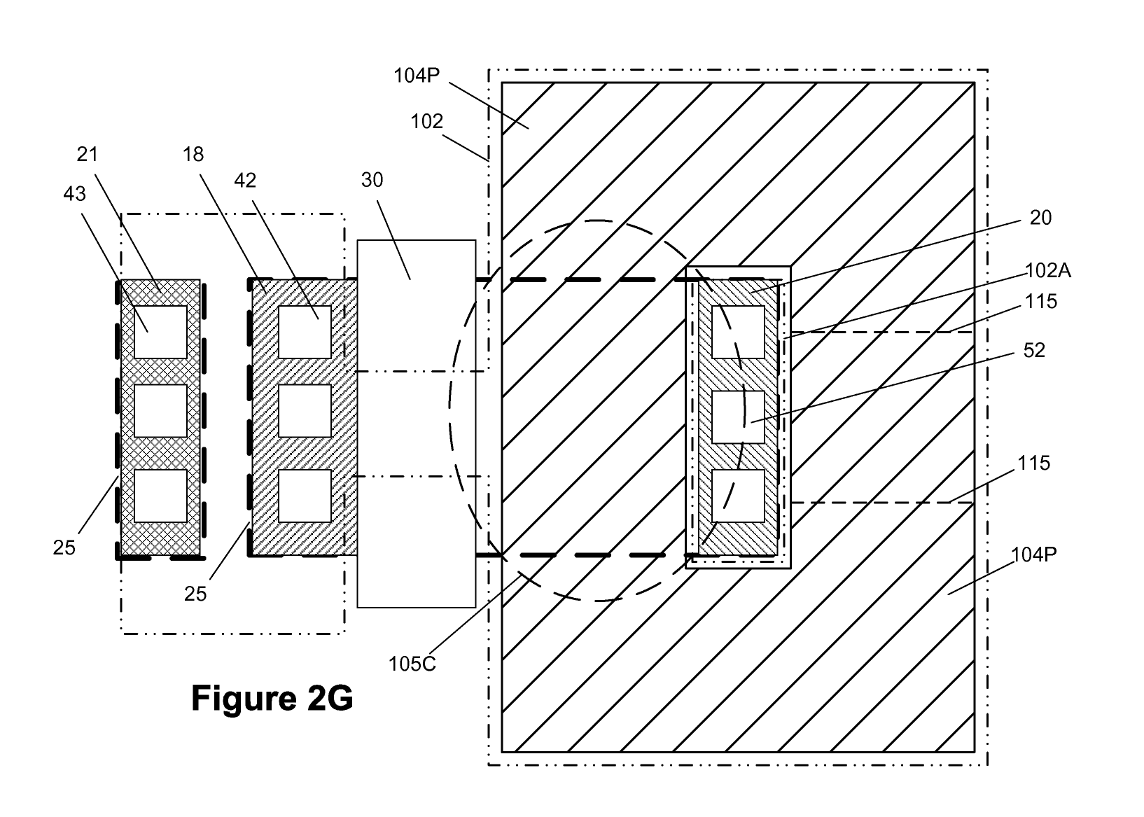

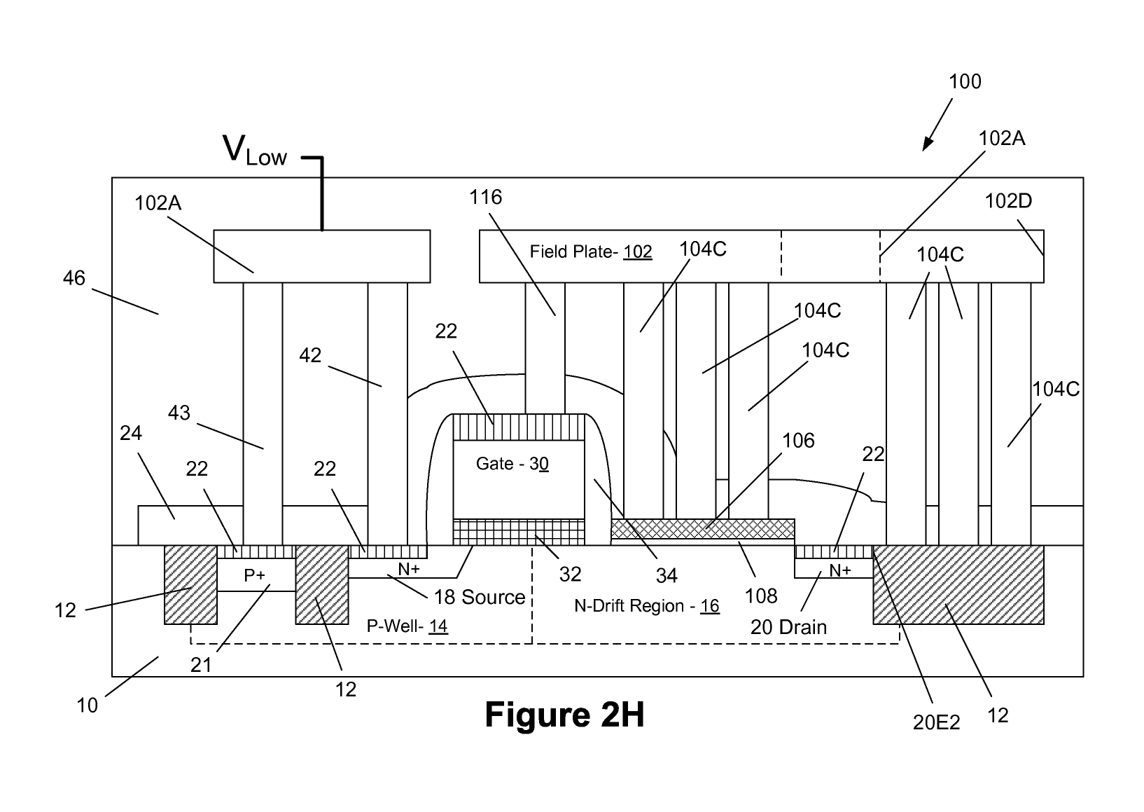

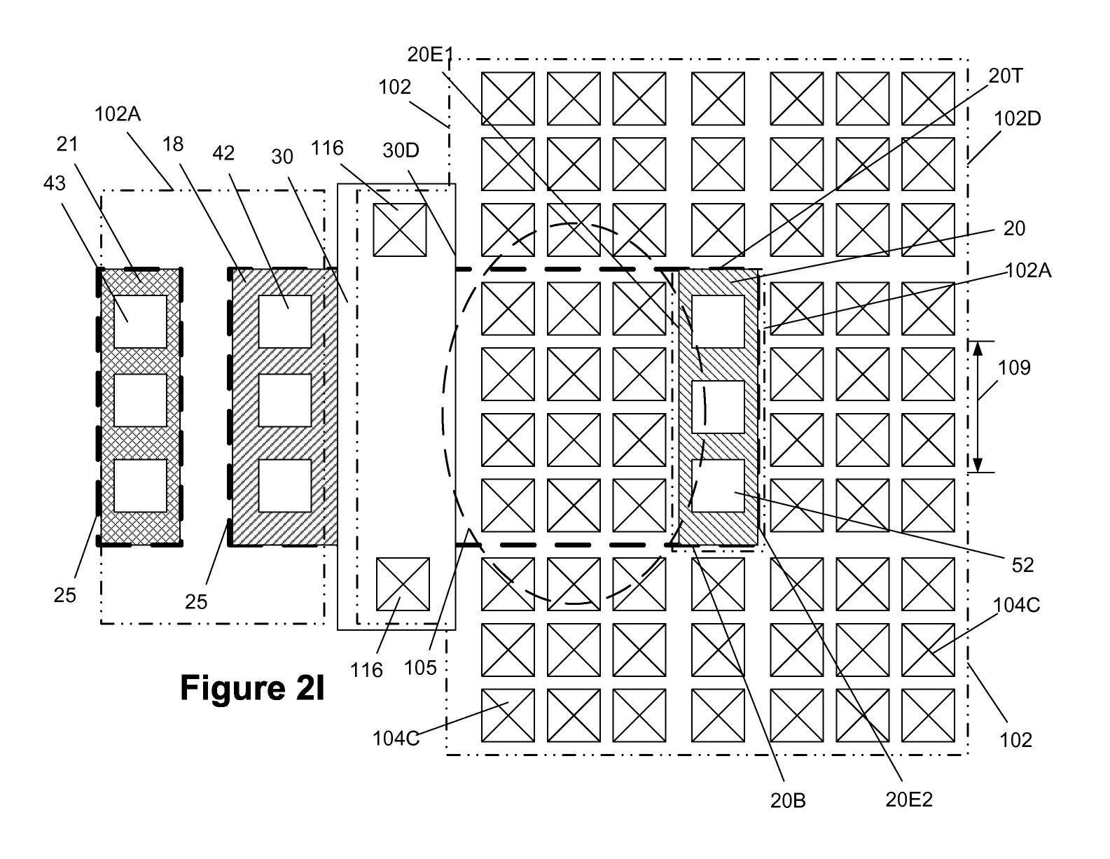

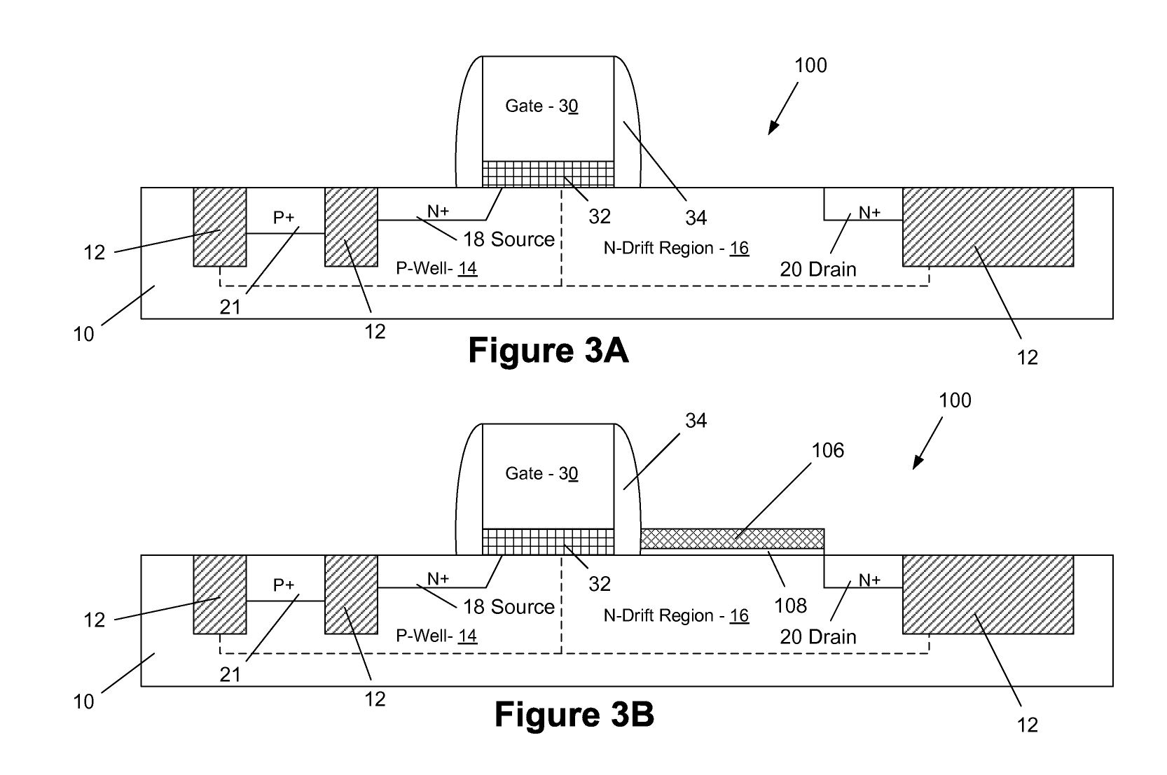

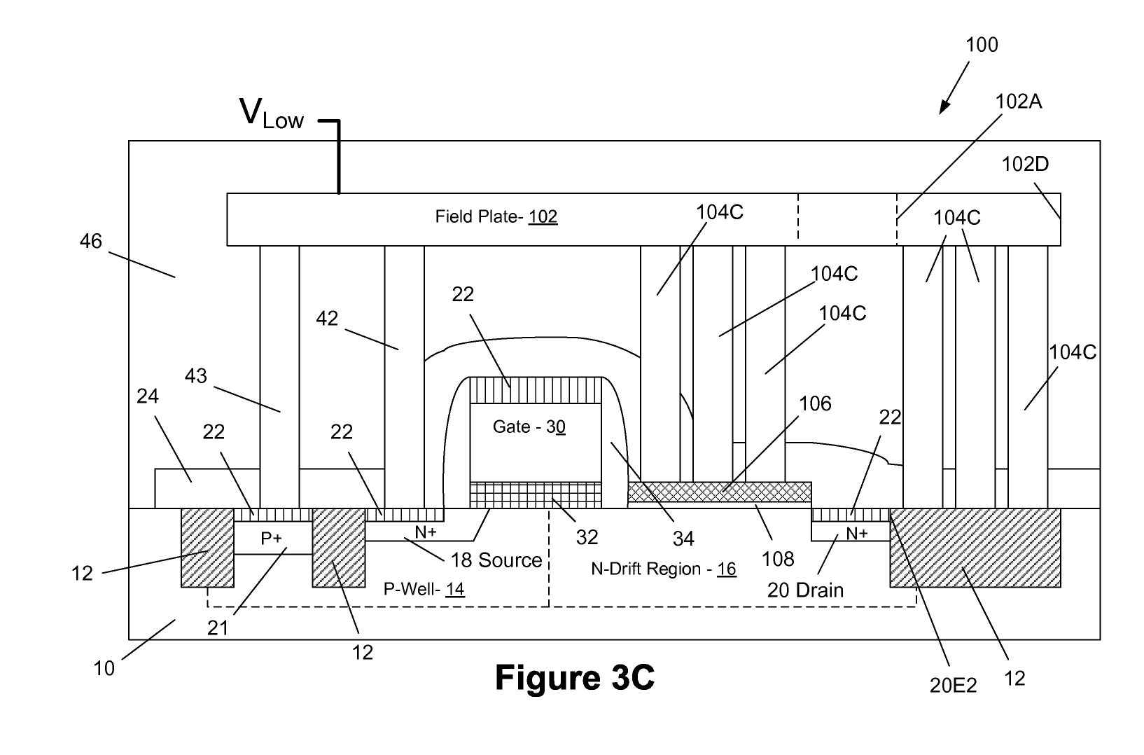

The present disclosure is directed to various embodiments of a novel LDMOS (Laterally Dispersed Metal Oxide Semiconductor) device with a novel field effect structure and various methods of making such an LDMOS device. As will be readily apparent to those skilled in the art upon a complete reading of the present application, the present method is applicable to a variety of devices, including, but not limited to, logic devices, memory devices, etc. With reference to FIGS. 2A-2I and 3A-3C, various illustrative embodiments of the methods and devices disclosed herein will now be described in more detail. To the extent that the same reference numbers are employed in FIGS. 2A-2I and 3A-3C as were used in FIGS. 1A-1B, the description of such structures and features shall apply equally to the device depicted in FIGS. 2A-2I and 3A-3C.

FIGS. 2A-2I schematically depict various illustrative embodiments of aspects of a novel LDMOS device 100 disclosed herein. In a general sense, in one broad aspect, the present disclosure is related to the formation of a novel field effect structure that is comprised of a plurality of conductive structures, generally designated with the reference numeral 104, that are conductively coupled to the metal-1 field plate 102, wherein at least some of the conductive structures 104 are positioned around or in close proximity to the drain region 20. As will be described more fully below, the conductive structures 104 may be comprised of a variety of different structures that may have different sizes and configurations and they may be positioned in a random or in an organized pattern. Moreover, the conductive structures 104 may be formed prior to the formation of the metal-1 field plate 102 or they may be formed at the same time as the metal-1 field plate 102 is formed. The conductive structures 104 are electrically coupled to a lower voltage than is present on the drain region of the device. For example, the conductive structures 104 may be conductively coupled to the source, the body or the gate electrode of the device, as these three structures are at a lower potential than the drain. In some cases, the conductive structures 104 may be conductively coupled to both the source and the body as those two regions are frequently tied together. As will be appreciated by one skilled in the art after a complete reading of the present application, the conductive structures 104 act to position a lower electrical potential nearer to the drain of the LDMOS device and thereby more effectively force the high electrical fields that are normally present near the drain side edge of the gate electrode farther away from the gate electrode toward the drain. In this manner, the breakdown voltage of the device is increased.

The LDMOS device 100 is formed above an illustrative semiconducting substrate 10, such as a silicon substrate having a bulk or so-called silicon-on-insulator (SOI) configuration. Of course, the substrate 10 may be comprised of a variety of materials other than silicon, depending upon the particular application. Various isolation regions 12 are formed in the substrate 10 using traditional techniques. In one illustrative embodiment, the LDMOS device 100 disclosed herein is also generally comprised of the previously mentioned P-well region 14, the N-doped drift region 16, the N+-doped source region 18, the N+-doped drain region 20 and the P+-doped well tap 21 that may be formed in the substrate 10 by performing traditional ion implantation techniques. The illustrative LDMOS device 100 is further comprised of the gate electrode 30, the gate insulation layer 32, the sidewall spacers 34, the various metal silicide regions 22, a layer of insulating material 24, such as a silicon nitride material, and a ILD layer 46, such as silicon dioxide. The gate electrode 30 is generally laterally positioned between the source region 18 and the drain region 20.

The device 100 further includes a metal-1 field plate 102, a plurality of source region contacts 42, a plurality of P-well region contacts 43, and, in the illustrative embodiment depicted in FIG. 2A, a plurality of field plate contacts 104C. In the illustrative example depicted in FIG. 2A, in the cross-section depicted therein, there are three of the field plate contacts 104C positioned beyond the outer edge 20E2 of the drain 20 and three of the field plate contacts 104C positioned between the inner edge 20E1 of the drain 20 and the gate electrode 30. FIGS. 2H and 2I depict an alternative configuration wherein the various conductive structures 104C are conductively coupled to the gate electrode 30 (which is at a lower voltage than the drain 20) via illustrative gate contacts 116. When employed, the gate contacts 116 may be conductively coupled to the gate electrode structure 30 and to the field plate 102 that is positioned at least partially above the gate electrode 30.

In one illustrative embodiment, each of the contacts 42, 43 and 104C are conductively coupled to a structure that has a relatively low voltage as compared to the voltage applied to the drain region 20. In the depicted example, the contacts 104C are electrically coupled to the source region 18 and the P-well doped tap 21 via a structure in the metal-1 layer of the device, e.g., the metal-1 field plate 102. In one illustrative embodiment, the metal-1 field plate 102 has a drain side edge 102D that extends laterally beyond the outer edge 20E2 of the drain region 20, and an opening 102A to allow for the formation of contacts (not shown in FIG. 2A) to the drain region 20. The LDMOS device 100 also may include an illustrative protection layer 108, such as a pad oxide layer, and a so-called silicide-block layer 106. In one illustrative embodiment, at least some of the field plate contacts 104C (or portions of larger merged versions of such contacts as described more fully below) contact or land on the silicide block layer 106. In some applications, the silicide block layer 106 may be formed so as to have a greater thickness than traditional prior art silicide block layers so as to insure that the field plate contacts 104C (or the other conductive structures 104 disclosed below) that are positioned above the silicide block layer 106 do not reach the underlying substrate 10, i.e., the N-drift region 16. In one illustrative embodiment, the protection layer 108 may be a layer of silicon dioxide having a thickness of about 20-80 nm, and the silicide block layer 106 may be a layer of silicon nitride having a thickness of about 10-40 nm.

With reference to FIG. 2B, further aspects of the illustrative LDMOS device 100 disclosed herein will now be described. FIG. 2B is a plan view of one illustrative embodiment of the metal-1 field plate 102 with only the illustrative gate structure 30 also being depicted so as to provide a frame of reference. The various doped regions and contacts that are positioned under the illustrative metal-1 field plate 102 are not depicted in FIG. 2B so as to avoid confusion and simplify the presentation. As shown in FIG. 2B, in one illustrative embodiment, the illustrative metal-1 field plate 102 has a generally rectangular shaped opening 102A to allow access for a plurality of conductive contacts (not shown) that will be formed to establish contact to the drain region 20 (not shown in FIG. 2B) that underlies the opening 102A. Of course, the size, number, shape and configuration of the opening 102A may vary depending upon the particular application. In some applications, the metal-1 field plate 102 may not completely surround the projected area of the drain region 20. For example, in some embodiments, the metal-1 field plate 102 may have an opening (defined by dashed lines 103) that permits access to the drain region 20.

With reference to FIG. 2C, further aspects of one illustrative embodiment of an LDMOS device 100 disclosed herein will now be described. The illustrative P+-doped well tap 21, the N+-doped source region 18 and the N+-doped drain region 20 (depicted with different shading in an effort to facilitate understanding) are formed in the active region 25 defined in the substrate 10 by one or more isolation structures 12 (not shown in FIG. 2C). As shown in FIG. 2C, the P-well region contacts 43 are conductively coupled to the P+ well region tap 21, the source region contacts 42 are conductively coupled to the source region 18 and the drain region contacts 52 are conductively coupled to the drain region 20. FIG. 2C is a plan view of the LDMOS device 100 where in one illustrative embodiment the silicide block layer 106 is depicted. For reference purposes, in the depicted orientation, the drain region 20 has an inner edge 20E1 (closer to the gate electrode 30), an outer edge 20E2 (more remote from the gate electrode 30), a top edge 20T and a bottom edge 20B. In this illustrative embodiment, the silicide block layer 106 extends from the sidewall spacer 34 all of the way to the inner edge 20E1 of the drain region 20. In other embodiments, depending upon the process flow selected, a portion of the silicide block layer 106 may extend above at least a portion of the gate electrode 30.

FIG. 2D is a depiction of one illustrative embodiment of a novel LDMOS device 100 described herein wherein the outline of the metal-1 field plate 102 and the opening 102A in the metal-1 field plate 102 are depicted in dashed lines so as to expose the various underlying contacts and to explain various aspects of the LDMOS device 100. As shown in FIG. 2D, the P-well region contacts 43 are conductively coupled to the P+ well region tap 21, the source region contacts 42 are conductively coupled to the source region 18 and the drain region contacts 52 are conductively coupled to the drain region 20. In one illustrative embodiment, the P-well region contacts 43 and the source region contacts 42 are conductively coupled to the metal-1 field plate 102, while the drain region contacts 52 are not electrically coupled to the metal-1 field plate 102. Instead, the drain regions contacts 52 are electrically coupled to a higher voltage supply than that applied to the metal-1 field plate 102 by any of a variety of different structures, such as a metal line (not shown) positioned above or below the metal-1 field plate 102. In FIG. 2D, the conductive structures 104 take the form of illustrative, rectangular-shaped field plate contacts 104C that are conductively coupled only to the metal-1 field plate 102, i.e., they are not in physical contact with any of the doped regions 21, 18, 16 or 20. In FIG. 2D, the field plate contacts 104C are depicted as a square with an “X” while the contacts 43, 42 and 52 to the various doped regions are depicted as a square without such an “X.” Of course, the various contacts 43, 42, 104C and 52, need not be of the same size or configuration, nor do they all to be made of the same conductive material, although such a configuration is possible.

With continuing reference to FIG. 2D, and as will be appreciated by those skilled in the art after a complete reading of the present application, the number and configuration of the illustrative field plate contacts 104C may vary depending upon the particular application. In the depicted example, the field plate contacts 104C basically define an array of field plate contacts 104C that is about 7 columns wide by 10 rows tall (as viewed on FIG. 2D), wherein the array of contacts 104C basically surrounds the drain region 20. Of course, it is not required that the drain region 20 be surrounded with the conductive structures 104 disclosed herein to practice at least some aspects of the various inventions disclosed herein, nor is it required that there be an equal number of the illustrative field plate contacts 104C on opposite sides of the drain region 20. For example, in some applications, only a single column of the field plate contacts 104C may be positioned outside of the outer edge 20E2 of the drain region 20, while there may be three such columns of the field plate contacts 104C positioned between the drain-side edge 30D of the gate electrode 30 and the inner edge 20E1 of the drain region 20. In a similar fashion, in some embodiments, there may not be any of the field plate contacts 104C positioned below the bottom 20B of the drain region 20 or above the top 20T of the drain region 20. Of course, the number of the field plate contacts 104C positioned above the top 20T of the drain region 20 and below the bottom 20B of the drain region 20 need not be equal. As another example, in some cases, some of the field plate contacts 104C may be omitted for a variety of reasons, e.g., the six field plate contacts 104C positioned outside of the outer edge 20E2 of the drain region 20 in the area defined by the line 109 may be omitted. Lastly, the layout of the various field plate contacts 104C need not be in a uniform or consistent pattern, as the spacing between the field plate contacts 104C and the relative positions of the field plate contacts 104C may vary depending upon the particular application. In one illustrative embodiment, the field plate contacts 104C that are completely within the dashed oval line 105 may land on the underlying silicide block layer 106 (not shown in FIG. 2D). The other field plate contacts 104C may land on isolation material, such as trench isolation regions, that are positioned outside of the active region 25.

FIG. 2E is a depiction of another illustrative embodiment of a novel LDMOS device 100 described herein, wherein, as was the case in FIG. 2D, the outline of the metal-1 field plate 102 and the opening 102A in the metal-1 field plate 102 are depicted in dashed lines so as to expose the various underlying contacts. As shown in FIG. 2E, the P-well region contacts 43 are conductively coupled to the P+ well region tap 21, the source region contacts 42 are conductively coupled to the source region 18 and the drain region contacts 52 are conductively coupled to the drain region 20. As was the case with the embodiment depicted in FIG. 2D, the P-well region contacts 43 and the source region contacts 42 are conductively coupled to the metal-1 field plate 102, while the drain region contacts 52 are not electrically coupled to the metal-1 field plate 102. Instead, the drain regions contacts 52 are electrically coupled to a higher voltage supply than that applied to the metal-1 field plate 102 by any of a variety of different structures, such as a metal line (not shown) positioned above or below the metal-1 field plate 102. In the illustrative example depicted in FIG. 2E, the conductive structures 104 take the form of a plurality of rectangular shaped ring-type structures 104R. In this illustrative example, the LDMOS devices comprises three illustrative conductive ring-type structures 104R1, 10482 and 104R3, each of which is conductively coupled only to the metal-1 field plate 102, i.e., they are not in physical contact with any of the doped regions 21, 18, 16 or 20. Of course, the number and position of the various conductive ring-type structures 104R1, 10482 and 104R3 may vary depending upon the particular application. The conductive ring-type structures 104R1, 10482 and 104R3 need not be of the same size or configuration, nor do they all need to be made of the same conductive material, although such a configuration is possible. In some applications, none of the conductive ring-type structures 104R1, 10482 and 104R3 may completely surround the drain region 20. That is, each of the conductive ring-type structures 104R1, 104R2 and 104R3 may not extend completely around the drain region 20. For example, portions of the conductive ring-type structures 104R1, 104R2 and 104R3 may be omitted in the area within the dashed lines 111. In other applications, only one or two of conductive ring-type structures 104R1, 104R2 and 104R3 depicted in FIG. 2E may be provided on the LDMOS device. In one illustrative embodiment, the portions of the conductive ring-type structures 104R1, 104R2 and 104R3 generally within the area within the dashed oval line 105A land on the underlying silicide block layer 106 (not shown in FIG. 2E). The other portions of the conductive ring-type structures 104R1, 104R2 and 104R3 may land on isolation material, such as trench isolation regions, that are positioned outside of the active region 25. Of course, if desired, a portion of one or more of the three illustrative ring-type structures depicted in FIG. 2E (or another ring-type structure) could be conductively coupled to the gate electrode 30 if desired.

FIG. 2F is a depiction of another illustrative embodiment of a novel LDMOS device 100 described herein, wherein, as was the case in FIGS. 2D-2E, the outline of the metal-1 field plate 102 and the opening 102A in the metal-1 field plate 102 are depicted in dashed lines so as to expose the various underlying conductive structures. As shown in FIG. 2F, the P-well region contacts 43 are conductively coupled to the P+ well region tap 21, the source region contacts 42 are conductively coupled to the source region 18 and the drain region contacts 52 are conductively coupled to the drain region 20. As was the case with the embodiment depicted in FIG. 2D, the P-well region contacts 43 and the source region contacts 42 are conductively coupled to the metal-1 field plate 102, while the drain region contacts 52 are not electrically coupled to the metal-1 field plate 102. Instead, the drain regions contacts 52 are electrically coupled to a higher voltage supply than that applied to the metal-1 field plate 102 by any of a variety of different structures, such as a metal line (not shown) positioned above or below the metal-1 field plate 102. In the illustrative example depicted in FIG. 2F, the conductive structures 104 take the form of a plurality of non-connected line-type structures 104L, each of which is conductively coupled only to the metal-1 field plate 102, i.e., they are not in physical contact with any of the doped regions 21, 18, 16 or 20. Of course, the number and position of the various conductive line-type structures 104L may vary depending upon the particular application. The conductive line-type structures 104L need not be of the same size or configuration, nor do they all need to be made of the same conductive material, although such a configuration is possible. In some applications, some of the line-type structures 104L may be combined so as to extend at least partially around a portion of the drain region 20. In other applications, portions of the conductive line-type structures 104L may be omitted in the area within the dashed lines 113. In one illustrative embodiment, the portions of the conductive line-type structures 104L that are generally positioned within the area within the dashed oval line 105B land on the underlying silicide block layer 106 (not shown in FIG. 2F). The other portions of the conductive line-type structures 104L may land on isolation material, such as trench isolation regions, that are positioned outside of the active region 25. Of course, if desired, a portion of one or more of the line-type structures 104L depicted in FIG. 2F (or another line-type structure) could be conductively coupled to the gate electrode 30.

FIG. 2G depicts yet another illustrative embodiment of a novel LDMOS device 100 described herein, wherein, as was the case in FIGS. 2D-2F, the outline of the metal-1 field plate 102 and the opening 102A in the metal-1 field plate 102 are depicted in dashed lines so as to expose the various underlying contacts. In the illustrative example depicted in FIG. 2G, the conductive structures 104 take the form of a generally rectangular shaped conductive plate 104P which is conductively coupled only to the metal-1 field plate 102, i.e., the conductive plate 104P does not physically contact any of the doped regions tap 21, 18, 16 or 20. Of course, the size and configuration of the conductive plate 104P may vary depending upon the particular application. In one illustrative embodiment, the conductive plate 104P is merely an extended part of the metal-1 field plate 102. Of course, the conductive plate 104P and the metal-1 field plate 102 need not be made of the same conductive material, although such a configuration is possible. In some applications, the conductive plate 104P may not completely surround the drain region 20, e.g., there may be an opening (indicated by dashed lines 115) through one or more sides of the conductive plate 104P (as it is viewed in FIG. 2G) that may provide access to the drain region 20. In one illustrative embodiment, the portions of the conductive plate 104P that are generally positioned within the area within the dashed oval line 105C may land on the underlying silicide block layer 106 (not shown in FIG. 2F). The other portions of the conductive plate 104P may land on isolation material, such as trench isolation regions, that are positioned outside of the active region 25. Of course, if desired, a portion of the illustrative conductive plate 104P depicted in FIG. 2G (or another plate-type structure) could be conductively coupled to the gate electrode 30.

FIGS. 2H-2I depict an illustrative embodiment of the device wherein a laterally smaller version of the metal-1 field plate 102 is not electrically coupled to the P-well region contacts 43 or the source region contacts 42. The P-well region contacts 43 and the source region contacts 42 are conductively coupled to another metal-1 conductive structure 102A that may also be coupled to a relatively low voltage supply. The illustrative field plate 102 depicted in FIGS. 2H-2I is conductively coupled to the gate electrode 30 via a plurality of illustrative gate contacts 116, which places the field plate 102, and the conductive contacts 104C that are electrically coupled to the field plate 102, at the same relatively lower voltage that is applied to the gate electrode 30.

FIGS. 3A-3C depict one illustrative process flow that may be performed to form various embodiments of the LDMOS devices disclosed herein. FIG. 3A depicts the device 100 at the point of fabrication where the isolation regions 12, the various implanted regions and the gate structure for the device 100 have been formed. The isolation regions 12 may be illustrative trench isolation regions that may be formed by etching various trenches into the substrate, depositing an insulating material into the trenches and thereafter performing a chemical mechanical polishing process. The various doped regions, e.g., P-well region 14, the N-doped drift region 16, the N+-doped source region 18, the N+-doped drain region 20 and the P+-doped well tap 21 may be formed in the substrate 10 by performing traditional ion implantation techniques through various masking layers (not shown). Thereafter, the gate structure comprised of the gate insulation layer 32 and the gate electrode 30 may be formed for the device 100. A gate cap layer (not shown) may also be formed above the illustrative gate electrode 30. The gate insulation layer 32 may be comprised of a variety of different materials, such as, for example, silicon dioxide, a so-called high-k (k greater than 10) insulation material, etc. Similarly, the gate electrode 30 may also be of a material such as polysilicon or amorphous silicon. In one illustrative embodiment, an oxidation process may be performed to form a gate insulation layer 32 comprised of silicon dioxide. Thereafter, a layer of gate electrode material, e.g., polysilicon, and a cap layer material (if employed), e.g., silicon nitride, may be deposited above the device 100 and the layers may be patterned using known photolithographic and etching techniques. Then, as shown in FIG. 3A, the sidewall spacers 34 are formed proximate the gate electrode 30. The spacers 34 may be made by conformably depositing a layer of spacer material, e.g., silicon nitride, and thereafter performing an anisotropic etching process.

Next, as shown in FIG. 3B, the protection layer 108 (if employed) and the silicide block layer 106 are formed above the device 100. In one illustrative embodiment, the protection layer 106 and the silicide block layer 106 are formed by depositing layers of their respective materials and thereafter performing one or more etching processes through a patterned mask layer (not shown).

FIG. 3C depicts the device 100 after several additional process steps have been performed. Using traditional silicidation techniques, metal silicide regions 22 are formed on the various doped regions 21, 18 and 20, as well as on the gate electrode 30. Thereafter, the insulation layer 24 and the ILD layer 46 may be blanket deposited across the device 100 using traditional deposition techniques, such as chemical vapor deposition (CVD) techniques. At this point in fabrication, the various conductive structures associated with the metal-1 field plate 102, such as the contacts 43 and 42 and the conductive structures 104 (e.g., field plate contacts 104C, conductive rings 104R1, 10482, 104R3, or the conductive plate 104P, or combinations of such structures) are formed above the device 100. The metal-1 field plate 102 may be formed at the same time as the contacts 43, 42 and the conductive structures 104, or the metal-1 field plate 102 may be formed after at least some or all of the contacts 43, 42 and the conductive structures 104 are formed. The metal-1 field plate 102 and the contacts 43, 42 and the conductive structures 104 may be made of any of a variety of different conductive materials, e.g., copper, aluminum, titanium, etc., and they need not all be made of the same material. Depending upon a variety of factors, the metal-1 field plate 102 and the contacts 43, 42 and the conductive structures 104 may be made using any of a variety of known techniques for fabricating such conductive structures, e.g., damascene techniques, traditional deposition/etching techniques, etc. Thus the materials of construction of the metal-1 field plate 102 and the contacts 43, 42 and the conductive structures 104, as well as the manner in which they are made, should not be considered to be a limitation of the present invention. The conductive contacts 52 to the drain region are not depicted in FIG. 3C. However, as will be appreciated by one skilled in the art, they may be formed at the same time, before or after the formation of the metal-1 field plate 102 and the contacts 43, 42 and the conductive structures 104.

Modeling of one illustrative example of the LDMOS device with one embodiment of the novel field effect structure disclosed herein has demonstrated a significant increase in the breakdown voltage of the LDMOS device 100 while the on-state resistance of the device remains essentially unchanged. In the modeling, the embodiment of the device 100 shown in FIG. 2D, i.e., the embodiment with the field plate 102 have the plurality of conductive contacts 104C that surrounded the drain region 20 coupled thereto, was compared to a prior art device having a similar metal-1 field plate arrangement as that depicted for the illustrative prior art LDMOS device shown in FIGS. 1A-1B. The breakdown voltage for the novel LDMOS device 100 disclosed herein was about 16.2 V while the breakdown voltage for the prior art LDMOS device 11 was about 13.8 V. The modeling indicated that the in line current was 19.3 μA/μm (for the novel LDMOS device 100 disclosed herein) and 19.4 μA/μm (for the prior art LDMOS device 11). Of course, the in line current measurement was an indirect measurement of the on-state resistance. As can be seen from this modeling data, the LDMOS device 100 exhibited about a 17% increase ((16.2−13.8)/13.8=0.174) in breakdown voltage over the prior art device with essentially no change in the on-state resistance of the devices.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An LDMOS device, comprising:
a source region and a drain region formed in a semiconducting substrate;
a gate electrode positioned above said substrate, said gate electrode being generally laterally positioned between said source region and said drain region;
a metal-1 field plate positioned above said gate electrode in a layer of insulating material that is formed above said substrate;
a silicide block layer formed above said substrate, said silicide block layer being positioned in an area between said gate electrode and said drain region;
at least one source contact that is conductively coupled to said metal-1 field plate; and
a conductive structure that is conductively coupled to said metal-1 field plate, wherein at least a first portion of said conductive structure extends downward toward said substrate in said area between said gate electrode and said drain region.

2. The device of claim 1, wherein said conductive structure comprises a plurality of individual conductive contacts.

3. The device of claim 1, wherein said conductive structure comprises a plurality of conductive rings.

4. The device of claim 1, wherein said conductive structure comprises a conductive plate.

5. The device of claim 1, wherein said conductive structure comprises a plurality of line-type structures.

6. The device of claim 1, wherein said first portion of said conductive structure extends downward toward said substrate and lands on said silicide block layer in said area between said gate electrode and said drain region.

7. The device of claim 1, wherein said conductive structure surrounds said drain region.

8. The device of claim 1, wherein said drain region is defined by multiple sides and wherein said conductive structure is positioned along a side of said drain region that is closest to said gate electrode.

9. The device of claim 1, wherein said metal-1 field plate has an edge that extends beyond a vertical projection corresponding to an outer edge of said drain region that is most remote from said gate electrode.

10. The device of claim 9, wherein said metal-1 field plate has an opening that is located above said drain region.

11. The device of claim 9, wherein a second portion of said conductive structure is laterally positioned beyond said outer edge of said drain region.

12. The device of claim 11, wherein said second portion of said conductive structure lands on a metal-1 field isolation structure formed in said substrate.

13. An LDMOS device, comprising:
a source region and a drain region formed in a semiconducting substrate;
a gate electrode positioned above said substrate, said gate electrode being generally laterally positioned between said source region and said drain region;
a metal-1 field plate positioned above said gate electrode in a layer of insulating material that is formed above said substrate;
a silicide block layer formed above said substrate, said silicide block layer being positioned in an area between said gate electrode and said drain region;
at least one source contact that is conductively coupled to said metal-1 field plate; and
a plurality of individual conductive contacts that are conductively coupled to said metal-1 field plate, wherein at least some of said plurality of individual conductive contacts extend downward toward said substrate and land on said silicide block layer in said area between said gate electrode and said drain region.

14. The device of claim 13, wherein said plurality of individual conductive contacts surrounds said drain region.

15. The device of claim 13, wherein said drain region is defined by multiple sides and wherein said plurality of individual conductive contacts are positioned along a side of said drain region that is closest to said gate electrode.

16. The device of claim 13, wherein said metal-1 field plate has an edge that extends beyond a vertical projection corresponding to an outer edge of said drain region that is most remote from said gate electrode.

17. The device of claim 16, wherein said metal-1 field plate has an opening that is located above said drain region.

18. The device of claim 16, wherein at least some of said plurality of individual conductive contacts are laterally positioned beyond said outer edge of said drain region.

19. An LDMOS device, comprising:
a source region and a drain region formed in a semiconducting substrate;
a gate electrode positioned above said substrate, said gate electrode being generally laterally positioned between said source region and said drain region;
a metal-1 field plate positioned above said gate electrode in a layer of insulating material that is formed above said substrate;
a silicide block layer formed above said substrate, said silicide block layer being positioned in an area between said gate electrode and said drain region;
at least one source contact that is conductively coupled to said metal-1 field plate; and
a plurality of line-type features that are conductively coupled to said metal-1 field plate, wherein at least one of said plurality of line-type features extends downward toward said substrate and lands on said silicide block layer in said area between said gate electrode and said drain region.

20. The device of claim 19, wherein said plurality of line-type features surrounds said drain region.

21. The device of claim 19, wherein said drain region is defined by multiple sides and wherein said plurality of line-type features are positioned along a side of said drain region that is closest to said gate electrode.

22. The device of claim 19, wherein said metal-1 field plate has an edge that extends beyond a vertical projection corresponding to an outer edge of said drain region that is most remote from said gate electrode.

23. The device of claim 22, wherein said metal-1 field plate has an opening that is located above said drain region.

24. The device of claim 22, wherein at least some of said plurality of line-type features are laterally positioned beyond said outer edge of said drain region.

25. An LDMOS device, comprising:
a source region and a drain region formed in a semiconducting substrate;
a gate electrode positioned above said substrate, said gate electrode being generally laterally positioned between said source region and said drain region;
a metal-1 field plate positioned above said gate electrode in a layer of insulating material that is formed above said substrate;
a silicide block layer formed above said substrate, said silicide block layer being positioned in an area between said gate electrode and said drain region;
at least one source contact that is conductively coupled to said metal-1 field plate; and
a plurality of ring-type features that are conductively coupled to said metal-1 field plate, wherein at least a portion of at least one of said plurality of ring-type features extends downward toward said substrate and lands on said silicide block layer in said area between said gate electrode and said drain region.

26. The device of claim 25, wherein each of said plurality of ring-type features surrounds said drain region.

27. The device of claim 25, wherein said metal-1 field plate has an edge that extends beyond a vertical projection corresponding to an outer edge of said drain region that is most remote from said gate electrode.

28. The device of claim 27, wherein said metal-1 field plate has an opening that is located above said drain region.

29. The device of claim 27, wherein at least a portion of said plurality of ring-type features are laterally positioned beyond said outer edge of said drain region.

30. An LDMOS device, comprising:
a source region and a drain region formed in a semiconducting substrate;
a gate electrode positioned above said substrate, said gate electrode being generally laterally positioned between said source region and said drain region;
a metal-1 field plate positioned above said gate electrode in a layer of insulating material that is formed above said substrate;
a silicide block layer formed above said substrate, said silicide block layer being positioned in an area between said gate electrode and said drain region;
at least one source contact that is conductively coupled to said metal-1 field plate; and
a conductive plate structure that is conductively coupled to said metal-1 field plate, wherein at least a first portion of said conductive plate structure extends downward toward said substrate and lands on said silicide block layer in said area between said gate electrode and said drain region.

31. The device of claim 30, wherein said conductive plate structure surrounds said drain region.

32. The device of claim 30, wherein said drain region is defined by multiple sides and wherein said conductive plate structure is positioned along a side of said drain region that is closest to said gate electrode.

33. The device of claim 30, wherein said metal-1 field plate has an edge that extends beyond a vertical projection corresponding to an outer edge of said drain region that is most remote from said gate electrode.

34. The device of claim 33, wherein said metal-1 field plate has an opening that is located above said drain region.

35. The device of claim 33, wherein at least a second portion of said conductive plate structure is laterally positioned beyond said outer edge of said drain region.
